(19) United States
(12) Patent Application Publication
(10) Pub. No.: US 2006/0224345 A1
(43) Pub. Date: Oct. 5, 2006

(54) System and method for improving electrical equipment accuracy by environmental condition compensation

(76) Inventors: Fred H. Ives, Veradale, WA (US); James B. Summers, Spokane Valley, WA (US); Brad E. Andersen, Spokane Valley, WA (US)

Correspondence Address: AGILENT TECHNOLOGIES INC.;INTELLECTUAL PROPERTY ADMINISTRATION, LEGAL DEPT,, M/S DU404, P.O. BOX 7599, LOVELAND, CO, 80537-0599, US

(21) Appl. No.: 11/098,695

(22) Filed: Apr. 4, 2005

(51) Int. Cl. G01R 35/00; G06F 19/00

(52) U.S. Cl. 702/107

(57) ABSTRACT

A system and method is designed to measure its own environmentally caused inaccuracies and, based upon these measurements, adjust itself to compensate for the inaccuracies. In one embodiment, a test system first measures the signal loss through a model “long” path constructed in the same substrate as is the main test circuit. Since the test path is constructed on the same substrate it then represents the actual environmental impact on the test circuit. The test signal is then sent through a “short” test path and the ratio difference from a reference measurement condition between the two paths yields the necessary compensation which is then used to calibrate the test circuit. In another embodiment, a test signal is applied across a capacitance made up of copper on different layers of substrate material. The actual environmental conditions on the substrate layers modify the measured capacitance value, which is then provided along with temperature as input to a model which determines compensation for the test circuit. Both embodiments can be applied to individual circuits or to systems that are subject to environmentally induced changes to their transmission line loss characteristics.

### BACKGROUND OF THE INVENTION

Changes in environmental humidity and temperature cause drift in the calibrated accuracy of high frequency signal generators, power meters, measuring receivers and other electronic test equipment. This equipment is expected to perform to specification in climates ranging from hot and dry to cold and wet. Typically this equipment is constructed using printed circuit boards made of dielectric materials which are affected by changes in temperature (dimensionally and electrically) and which absorb water from the environment. As a result, the insertion loss and characteristic impedance of transmission line structures fabricated on these boards will vary with changes in environmental conditions. This variation affects the calibrated accuracy of the test equipment. Since the environment in which the test equipment is calibrated can differ from that in which it is to be used, allowances must be made in the equipment specification setting process to be able to guarantee the specified level of performance over a range of environmental conditions. These allowances result in poorer performance specifications for the equipment than would be possible if the environmental variation did not exist.

Typically, some form of temperature compensation is incorporated into the equipment design. Ambient temperature is fairly easy to sense and the equipment performance is characterized as a function of this temperature. During operation, corrections are made to compensate for ambient temperature variation. Many instrument specifications require that the instrument must be powered on for some period of time to allow the relationship between ambient temperature and the instrument internal temperature to stabilize. Depending on the instrument's design, this time period can range from minutes to hours. The effectiveness of this temperature compensation is limited because not all points in the equipment chassis are at the same temperature, the temperature characteristics of various printed circuit assemblies differ, and the effects of moisture absorption are uncompensated.

### BRIEF SUMMARY OF THE INVENTION

It has been observed that not only do the current environmental conditions impact equipment inaccuracies but the cumulative past environmental conditions also act to change the accuracy. Taking this observation into consideration, a system and method is designed to first measure parameters related to its own environmentally induced inaccuracies and then based upon these measurements, the system adjusts itself to compensate for the inaccuracies.

In one embodiment, an insertion loss sensing system is formed by a long transmission line and a short transmission line. An RF source and detector are used to measure the difference between the insertion losses of these two transmission lines. This difference in insertion loss, and the difference in length between the two transmission lines, provides a measure of the loss per unit length of transmission lines formed on the same substrate (or similar substrates) as the insertion loss sensing system. By capturing the loss per unit length data at the time the electronic test equipment is calibrated, and again at time intervals during operation of this equipment, it is possible to determine changes in the equipment's calibration due to changes induced by the environmental conditions.

In another embodiment, the capacitance of parallel plate capacitors formed by copper areas on the printed circuit boards are measured. Capacitance and board temperature are measured at the time the equipment is calibrated, and the data is stored in non-volatile memory. During operation, capacitance and temperature are measured again (at time intervals). The values measured at calibration time and those during operation are fed into an algorithm which models the board's environmental behavior. This algorithm then produces a correction factor which is used to compensate for the environmentally induced change from the original calibrated performance.

The foregoing has outlined rather broadly the features and technical advantages of the present invention in order that the detailed description of the invention that follows may be better understood. Additional features and advantages of the invention will be described hereinafter which form the subject of the claims of the invention. It should be appreciated by those skilled in the art that the conception and specific embodiment disclosed may be readily utilized as a basis for modifying or designing other structures for carrying out the same purposes of the present invention. It should also be realized by those skilled in the art that such equivalent constructions do not depart from the spirit and scope of the invention as set forth in the appended claims. The novel features which are believed to be characteristic of the invention, both as to its organization and method of operation, together with further objects and advantages will be better understood from the following description when considered in connection with the accompanying figures. It is to be expressly understood, however, that each of the figures is provided for the purpose of illustration and description only and is not intended as a definition of the limits of the present invention.

### BRIEF DESCRIPTION OF THE DRAWINGS

For a more complete understanding of the present invention, reference is now made to the following descriptions taken in conjunction with the accompanying drawings, in which:

FIG. 1 shows one embodiment of an RF signal trace on a board;

FIG. 2 shows one embodiment of a method for calibrating electronic equipment;

FIG. 3A illustrates one embodiment of a system and method for using an equivalent circuit path for determining environmental loss error;

FIG. 3B illustrates one embodiment of a circuit for utilizing the concepts of the invention;

FIG. 4A illustrates one embodiment for using capacitance and temperature measurement to determine dielectric characteristic changes which are then applied to a model to determine environmentally induced performance (gain) changes

FIG. 4B illustrates one embodiment of a circuit and method block diagram which utilizes the capacitance and temperature measurement concept of the invention.

### DETAILED DESCRIPTION OF THE INVENTION

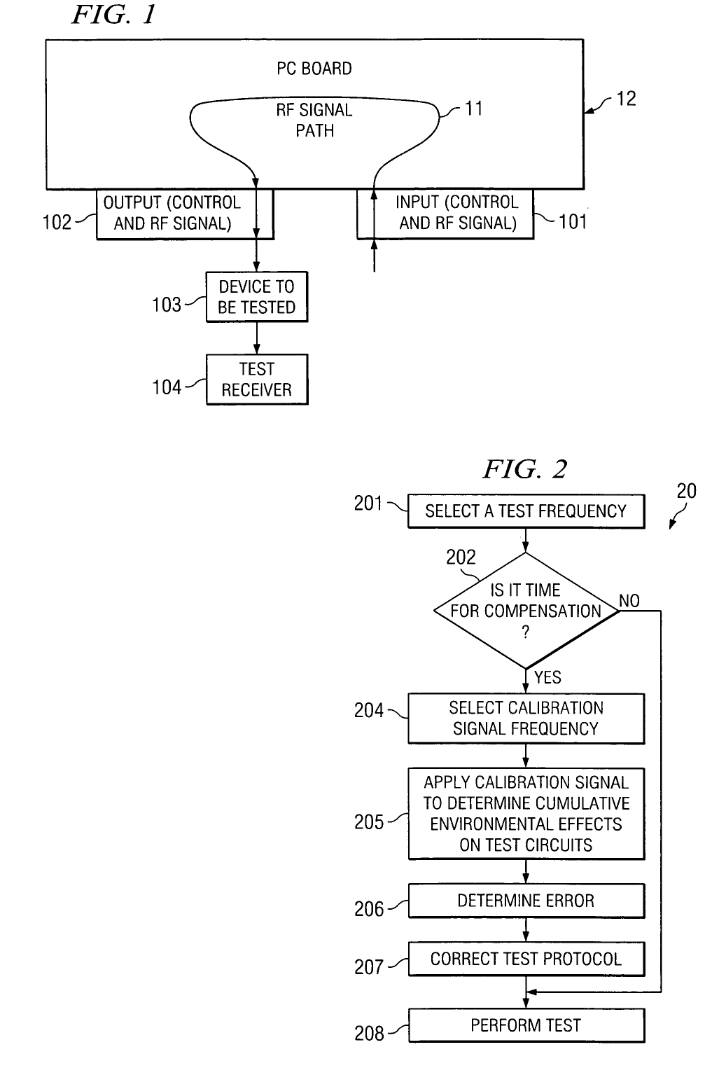

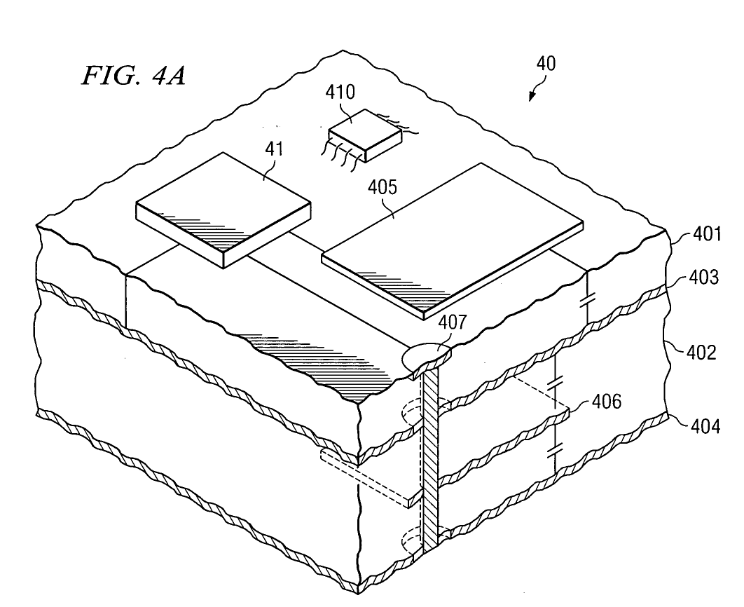

FIG. 1 shows one embodiment of a representative circuit board 12 in an RF instrument illustrating representative signal path 11 extending from input 101 through the board and through various circuits thereon (shown in FIG. 3B) to signal output 102. Note that, if desired, the input signal could be generated on board 12 instead of on a separate circuit.

In operation, in one embodiment, a signal (such as from source 31 FIG. 3A) is selected as an input to the RF test circuitry 300 (shown in FIG. 3B and represented on FIG. 1 as path 11). In one embodiment, an output from path 11 is applied to device under test (DUT) 103. An output from DUT 103 is then applied to test receiver 104 to determine if the DUT is within a range. Alternately, DUT 103 could output its own signal which is then received by test receiver 104. In some situations the test signal generator and the test receiver are in the same housing of a measurement test system.

A typical board dimension for board 12 would be 11.2″ wide and 5.2″ high, with the typical RF signal path 11 having a length between 15″ and 24″. PC board 12 is typically constructed from one of several different board materials such as, FR4, GETEK™, or Rogers™ 4350. These materials will absorb moisture over a period of time and this moisture affects the loss characteristic of RF signals propagating on transmission lines formed on these boards which is also dependent on temperature for any given moisture content.

RF System designers are putting more and more functionality into a single RF module, which typically contains one of these boards. The RF path on a board will typically contain amplifiers, mixers, filters, modulators, switches, and power splitters to generate an RF signal having a desired frequency and other parameters. Signals are isolated from one another by ground planes and internal walls with gaskets on the front and back covers. Typical overall path losses for these types of paths in GETEK™ are from 0.75 to 1.5 dB at 500 MHz, from 1.5 to 2.4 dB at 1,000 MHz and from 3.0 to 4.8 dB at 2,500 MHz. The loss variation depends on the type of PC board dielectric material. For example, the path losses for FR 4 material are a little more than the values shown above and the path losses for Rogers™ 4350 material are about one-half these values.

The loss variation also depends on the type of RF path. Microstrip, on an outer surface of the board, has the lowest loss and stripline, inside a multilayer board between two ground planes, is higher in loss. Different types of shielding and matching require the use of both microstrip and stripline structures. Using a GETEK™ design and depending on the RF path length, the loss on a board can vary as much as 1.5 dB at 2,500 MHz due to environmentally induced changes caused by temperature and humidity.

In a specific example of an RF signal generator design, present calibration procedures can take out most of the observed 0.6 dB variation down to a level below 0.1 dB uncertainty immediately following the calibration. However, since calibration is intrusive, it is normally limited to being performed once per day. Under such a once a day procedure it has been observed that environmental loss uncertainty can be lowered to only 0.3 dB. By adding together all the uncertainties of measurement, manufacturing and yield, a typical RF source accuracy using the once per day calibration procedure yields a +/−1.0 dB accuracy specification. Note that with only a factory calibration and no further once a day calibration, the accuracy spec would be +/−1.3 dB due to environmental conditions. Using the compensation concepts described herein it is anticipated that as much as 0.4 to 0.5 dB error can be removed so as to achieve an overall RF source accuracy specification of +/−0.8 to 0.9 dB from 500 MHz to 2500 MHz. Circuit designs with longer traces and/or with more stripline traces could achieve even greater improvement than in this example. Since environmental compensation can be applied for each test performed, if desired, the initial (or subsequent) device calibrations need not be performed as often. Also, since the compensation adjusts for environmental conditions, such as moisture, there is no need to allow the circuitry to “dry out” prior to running a test protocol on a piece of equipment.

Since PC board transmission line losses are the biggest source of the humidity and temperature induced errors, systems that have more PC boards or longer PC board RF path lengths, can achieve much improved calibration accuracy using the concepts discussed herein.

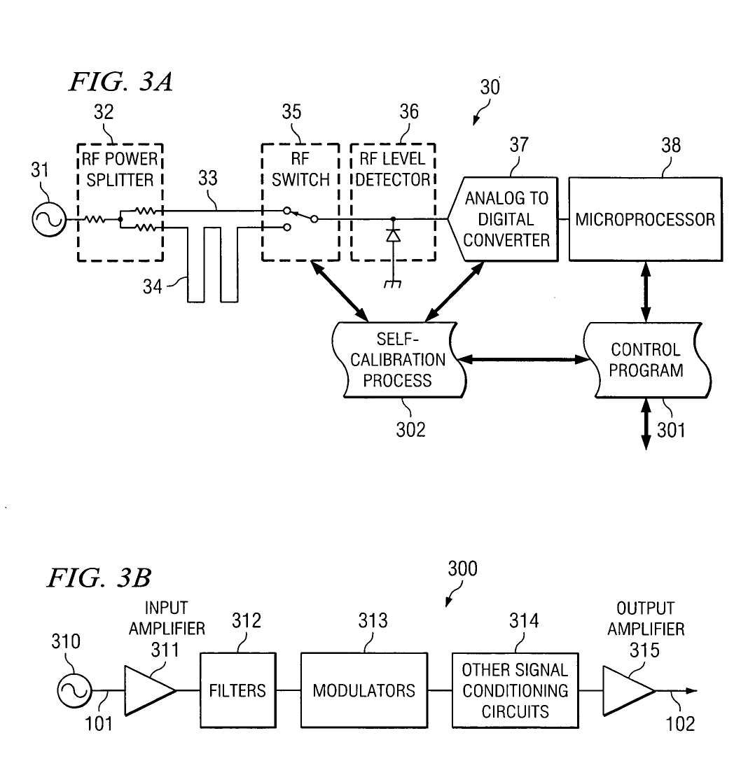

FIG. 2 shows one embodiment 20 of a method for calibrating electronic equipment, such as, for example, signal generators, signal measuring receivers, power meters and the like. In the embodiment shown, the equipment to be compensated is test equipment in a frequency range between 500 MHz and 2,500 MHz, but the procedures discussed herein can be utilized for any equipment having RF signals that are affected by environmental effects on a circuit board.

Process 202 determines if it is time for an environmental compensation to be run on the circuit according to certain parameters. These parameters are determined when the circuit is designed and characterized over the expected environmental conditions. This step can be avoided, if desired and the compensation can be performed on a continuous or periodic basis. If the compensation is not to be performed, then the test signal is produced (or in the case of a measurement device, measured) using the selected test frequency via process 207 by, applying the last correct test protocol. If environmental compensation is to be performed, then process 204 selects a calibration signal frequency based upon the selected frequency of the test protocol. Process 205 applies the calibration signal as will be described to determine the cumulative environmental effect on the RF circuit trace. Using this cumulative effect determination, process 206 determines the loss error to the RF signal based upon the environmental conditions. Process 207 applies correct compensation to the test protocol at the selected test frequency or adjusts the receiving circuitry by compensating the receiving circuitry for the effects of the environmental conditions. Process 208 then performs the test on the actual equipment (not shown) according to the test protocol selected for the test RF signal.

Note that since the compensation can be done internally, processes 204-207 could be initiated at any time and in fact can be done at times when the system is not being utilized for actual testing thereby further maintaining the accuracy of the system by reducing compensation related downtime as well as inaccurate readings.

FIG. 3A illustrates one embodiment 30 of a system and method utilizing a measured board loss change in an equivalent circuit path (34) to determine the change in the loss in the actual RF path 300 (FIG. 3B). Since the PC board accumulates loss changes from moisture as absorbed by the board in its particular environment over time, it is possible to create within the PC board (or on a separated board if desired) a representative path 34, herein called the long path, which is used to determine a ratio between path 34 and short path 33 which effectively allows for the monitoring of environmental differences since a prior calibration. The long (or mock) path is created in the same substrate (or in a substrate having the same physical properties when exposed to moisture over time) as is the actual RF path so that it is representative of the moisture and temperature effects over time experienced by the actual RF path.

This procedure can be accomplished in one of many ways. For example, calibration source 31 is applied to RF power splitter 32 which sends the calibration signal through short trace 33 and through long trace 34. RF switch 35 under control of self calibration process 302, which in turn is under control of control program 301, switches back and forth between the short path (trace) and the long path (trace). The outputs from each trace are detected via RF level detector 36, converted to digital values via A to D converter 37 and presented to microprocessor 38. Control program 301 then determines the ratio between the short trace and the long trace to arrive at a loss approximation as to how environmental conditions have changed actual test circuit 300 (shown in FIG. 3B). Note that long path 34 and short path 33 can be constructed on the same substrate as the actual circuit to be compensated (circuit 300) or they can be created on a separate board using materials that react similarly to the environmental conditions as the materials used in the boards of the actual RF circuitry 300 to be compensated.

FIG. 3B shows RF circuitry 300 to be compensated which is adjusted under control program 301 to yield proper test results regardless of environmental conditions. Thus, as shown in FIG. 3B, signal source or synthesizer 310 is provided to input amplifier 311 which goes to filters 312, modulators 313 and other signal conditioning circuits 314 to output amplifier 315. Output amplifier 315 or any of the other elements, in circuit 300 have been adjusted by the control program 301 to compensate for the current environmental conditions as determined by the circuitry of FIG. 3A based on a measured difference due to humidity and temperature working on the substrate. In this manner output 102 of test circuit 300 is compensated for the environmental effects which have accumulated over a period of time.

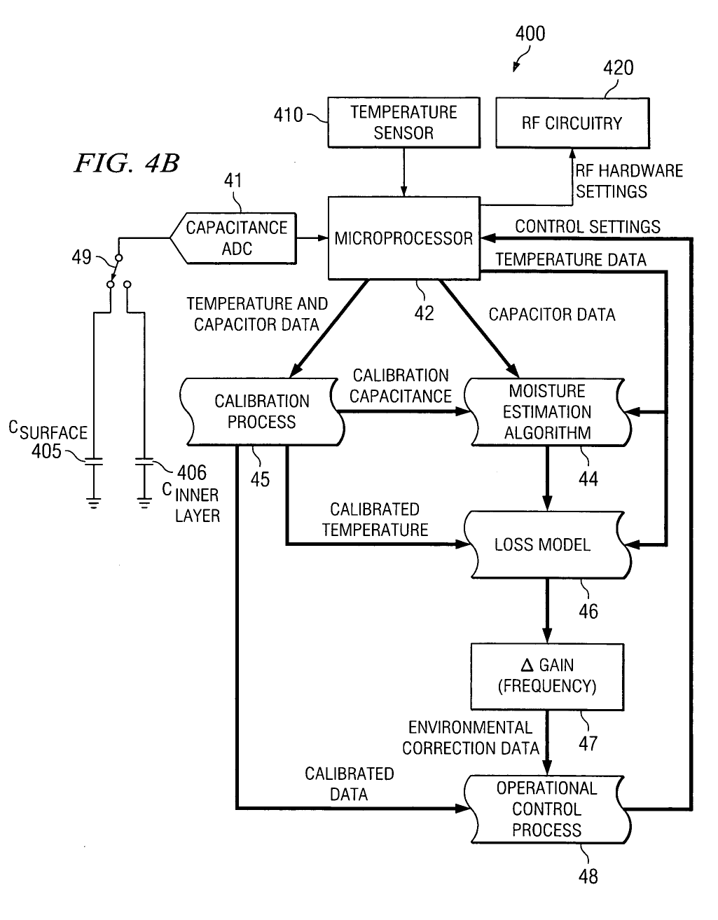

FIG. 4A illustrates one example of a system and method using measured capacitance and temperature changes as inputs to a model to estimate the actual loss to be expected in the RF path. Structure 40, a multi-layer printed circuit board, absorbs moisture from the environment. As this moisture enters the board, it changes the dielectric constant of the board material since the permittivity of water is higher than that of the board material. A capacitor is formed between copper area 405 and ground plane 403. Board dielectric layer 401 forms the dielectric for this capacitor. Sensing changes in the capacitance of this capacitor structure provides information about the moisture content in board dielectric layer 401 which will affect surface microstrip transmission line losses. Similarly, a capacitor is formed between copper area 406 and ground planes 403 and 404 with board dielectric 402 forming the capacitor dielectric. Sensing changes in capacitance of this capacitor structure provides information about the moisture content in board dielectric 402, which will affect internal stripline transmission line losses.

Capacitance measurement circuitry 41 is connected to copper area 405 by a surface printed circuit trace and to copper area 406 by plated printed circuit via hole 407. Temperature measurement circuitry 410 senses the temperature of the printed circuit board. Capacitance measurement circuitry 41 and temperature measurement circuitry 410 can both be realized advantageously using ADC model AD7747 available from Analog Devices, Inc. This ADC is a two channel capacitance to digital converter which provides high resolution capacitance measurement and also contains an on-chip temperature sensor.

FIG. 4B illustrates an environmental compensation system 400. Microprocessor 42 receives input from temperature sensor 410 and capacitance sensor 41. This information is provided to calibration process 45 at the time process 45 generates calibration data for RF circuitry 420 on the printed circuit board associated with system 400. This calibration data is typically RF gain as a function of RF frequency, and is used by control process 48 to make hardware control settings in RF circuitry 420, via microprocessor 42. The capacitance and temperature data presented to calibration process 45 represent the board environmental condition at the time the RF circuitry calibration data is generated.

During normal operation, microprocessor 42 collects temperature and capacitance data periodically and presents the data to moisture estimation algorithm 44. Moisture estimation algorithm 44 provides an estimate of the change in printed circuit board moisture content since calibration to loss model 46. Loss model 46 takes the moisture change and the temperature change since the original RF circuitry calibration data was generated and produces a set of data 47 which predicts the change in RF circuit performance as a function of operating frequency. Data 47 is then used, along with the RF circuitry calibration data produced by calibration process 45, by operational control process 48 to make settings in the RF circuitry to produce calibrated operation with compensation for the environmental effects.

Since various dielectric substrate materials may be used to fabricate printed circuit boards in a test instrument, different moisture estimation algorithms (44) may be required for circuit boards of differing construction. Loss model 46 is not only circuit board construction dependent; it is dependent on the RF circuit design itself. Thus, each design will require a unique loss model. This model is typically generated by correlating moisture and temperature changes, during controlled environmental characterization testing, to measured RF circuit performance.

Placement of the capacitive and temperature sensors can impact the accuracy of the environmental compensation. Water absorption by the board dielectric is a relatively slow process and absorption rates may differ from one area of a board to another. For example, water incursion will occur faster near the edges of a PC board. For maximum accuracy, the sensors need to be placed such that conditions in critical circuit areas are accurately reflected by the sensor data.

Note also that while the calibration of a test signal output (signal generator) has been discussed, a receiving circuit (measuring receiver), or a power meter, or any other type of equipment that is sensitive to calibration parameters, can also be calibrated. In fact, the signal generator, the signal receiver or both can be calibrated, if desired, in the same system.

Although the present invention and its advantages have been described in detail, it should be understood that various changes, substitutions and alterations can be made herein without departing from the spirit and scope of the invention as defined by the appended claims. Moreover, the scope of the present application is not intended to be limited to the particular embodiments of the process, machine, manufacture, composition of matter, means, methods and steps described in the specification. One of ordinary skill in the art will readily appreciate from the disclosure of the present invention, any processes, machines, manufacture, compositions of matter, means, methods, or steps, that presently exist or that will be developed that perform substantially the same function or achieve substantially the same result as the corresponding embodiments described herein may be utilized according to the present invention. Accordingly, the appended claims are intended to include within their scope such processes, machines, manufacture, compositions of matter, means, methods, or steps.

What is claimed is:

1. An electrical circuit comprising:
circuitry for generating an output signal having a certain set of characteristics, said characteristics subject to change dependant upon the present environmental loss characteristics of said electrical circuit;
means for determining the present environmental loss characteristics of said electrical circuit; and
means controlled at least in part by said determining means for maintaining said certain set of characteristics without regard to said present environmental loss characteristics of said electrical circuit.

2. The circuit of claim 1 wherein said circuitry is contained on a substrate and wherein said determining means comprises:
means for propagating signals through a path constructed on said substrate.

3. The circuit of claim 1 wherein said determining means comprises:
means for propagating signals through a test path constructed to yield an output signal, which is characteristic of the present environmental loss characteristics of said electrical circuit.

4. The circuit of claim 1 wherein said maintaining means makes corrections for environmental changes to improve the accuracy of a measuring receiver.

5. The circuit of claim 4 wherein said accuracy improvement is in the range of +/−0.4 to 0.5 dB from 500 MHz to 2,500 MHz.

6. The circuit of claim 1 wherein said maintaining means makes corrections for environmental changes to improve the accuracy of a power meter.

7. The circuit of claim 6 wherein said accuracy improvement is in the range of +/−0.4 to 0.5 dB from 500 MHz to 2,500 MHz.

8. The circuit of claim 1 wherein said maintaining means makes corrections for environmental changes to improve the accuracy of a measurement test system, said system comprising at least one signal from the list of: signal generators, measuring receivers, power meters.

9. The circuit of claim 8 wherein said accuracy improvement is in the range of +/−0.4 to 0.5 dB from 500 MHz to 2,500 MHz.

10. The method of testing equipment in an environment in which moisture changes the test signal along a signal trace on a substrate; said method comprising compensating said test signal for the cumulated effects of said moisture.

11. The method of claim 10 wherein said compensating comprises:
propagating a calibration signal along a test path constructed such that said cumulated effects of said moisture can be determined.

12. The method of claim 10 wherein said test path is constructed in said substrate.

13. The method of claim 11 wherein said test path is constructed in a material having a response to moisture similar to the response to moisture of said substrate.

14. The method of claim 10 wherein said compensations comprises:
measuring capacitance changes in a material having a response to moisture in a known relationship to the moisture response of said substrate.

15. A test system comprising:
a signal generator;
a signal measuring receiver;
circuitry for determining the present environmental loss characteristics of said signal generator and said signal measurement receiver; and
circuitry operative in response to said determining circuitry for adjusting either said signal measuring receiver or said signal generator or both said signal measuring receiver and said signal generator to account for said present environmental loss characteristics of said electrical circuit.

16. The system of claim 15 wherein said determining circuitry comprises:
circuitry for propagating signals through at least one test circuit constructed to yield an output signal which is characteristic of the present environmental loss characteristics of said signal generator and said signal measurement receiver.

17. The system of claim 14 wherein said signal generator is contained on a first substrate and wherein said signal measuring receiver is contained on a second substrate; and wherein
said circuitry for determining the present environmental loss characteristics of said signal generator comprises, at least in part, test circuitry constructed on said first substrate; and
said circuitry for determining the present environmental loss characteristics of said signal measuring receiver comprises, at least in part, test circuitry constructed on said second substrate.

18. The system of claim 15 wherein said adjusting circuitry makes corrections for environmental changes to improve the accuracy of said signal generator or said signal measuring receiver or both said signal generator and said signal measuring receiver.

19. The system of claim 18 wherein said adjusting circuitry makes corrections for environmental changes to improve the accuracy of said signal generator or said signal measuring receiver or both said signal generator and said signal measuring receiver.

20. The method of calibrating a test protocol, said method comprising:
generating a test protocol compensation data under control of circuitry constructed on at least one substrate having a certain set of physical properties, said physical properties influenced by accumulated environmental conditions in a manner similar to the influence said environmental conditions exert on the circuitry controlling an actual test.

21. The method of claim 20 wherein said generation comprises propagating a calibration signal along a test path constructed such that the cumulative effects of the environment on said test protocol can be determined from said calibration signal thereby allowing said test protocol to be adjusted for the cumulative effects of said environment on said test equipment.

22. The method of claim 21 wherein said test protocol comprises high frequency signals.

23. The method of claim 22 wherein said propagating comprises sending a calibration signal along a test path constructed on a substrate having said certain set of physical properties thereby allowing said test protocol to be adjusted for the effects of environment on said test equipment.

24. The method of claim 23 wherein said propagating further comprises sending said test signal along a long path and a short path of said substrate to arrive at a ratio, said ratio representing said effects of said environment.

25. The method of claim 23 wherein said test path substrate and said protocol control circuitry substrate are together on the same substrate.

26. The method of claim 23 wherein said test path is in equipment separate from said at least one protocol control substrate.

27. The method of claim 20 wherein the test protocol comprises:
measuring circuit board temperature, and
measuring the capacitance of a capacitor formed using the circuit board material as a dielectric.

28. The method of claim 27 wherein said measuring is such that said cumulative effects of the environment on said test protocol can be determined from a set of computations to determine environmental correction data for the test protocol.

29. The method of claim 28 wherein said measuring comprises measuring the capacitance of capacitors formed on a plurality of layers of said circuit board.

30. The method of claim 29 wherein said measuring:
comprises measuring the circuit board temperature and capacitance of capacitors formed on a plurality of layers of a separate multi-layer material having properties similar to the properties of said circuit board.

31. The method of claim 30 wherein said capacitance measurement is performed using a capacitance analog to digital converter.

32. The method of claim 20 wherein said test protocol is used to improve the accuracy of at least one device selected from the list of signal generators; measuring receivers; power meters.

33. The method of claim 32 wherein said test protocol is used to improve the accuracy of at least one device selected from the list of signal generators; measuring receivers; power meters.

34. The method of calibrating electronic test equipment comprising:
at a point in time, initially calibrating an RF signal to compensate for inaccuracies in said RF signal; and
at a later point in time recalibrating said RF signal to compensate for changes to said RF signal caused by the cumulative effects of moisture and temperature on the circuit board containing the RF path through which said RF signal propagates.

35. The method of claim 34 wherein said recalibrating achieves an overall RF source accuracy specification improvement of +/−0.4 to 0.5 dB from 500 MHz to 2,500 MHz.

36. The method of claim 35 wherein said recalibrating comprises:
sending an RF calibration signal along a test path constructed in material having properties similar to the properties of said circuit board.

37. The method of claim 36 wherein said recalibrating further comprises:
sending said RF calibrating signal so that it is alternately applied to a short version of said test path as well as to said mock path so as to provide a ratio between the mock path and the short path to allow for RF signal changes only between said initial calibrating and said recalibrating to effect said recalibrating.

38. The method of claim 35 wherein said recalibrating comprises:
measuring circuit board temperature, measuring the capacitance of a capacitor formed using the circuit board material as dielectric; and
applying a set of computations to determine environmental correction data.

39. The method of claim 36 wherein said capacitance measuring comprises:
measuring the capacitance of capacitors formed on a plurality of layers of said circuit board.

40. The method of claim 39 wherein said capacitance measuring is performed using a capacitance analog to digital converter.
